(19) United States
(12) Patent Application Publication
(10) Pub. No.: US 2024/0194479 A1
(43) Pub. Date: Jun. 13, 2024

(54) METHODS AND APPLICATIONS OF NOVEL AMORPHOUS HIGH-K METAL-OXIDE DIELECTRICS BY SUPER-CYCLE ATOMIC LAYER DEPOSITION

(71) Applicant: Applied Materials, Inc., Santa Clara, CA (US)

(72) Inventors: Zhelin Sun, Sunnyvale, CA (US); Kwang Soo Huh, Palo Alto, CA (US); Lai Zhao, Campbell, CA (US); Soo Yong Choi, Fremont, CA (US)

(21) Appl. No.: 18/555,342

(22) PCT Filed: Apr. 22, 2021
(86) PCT No.: PCT/US21/28711

§ 371 Date: Oct. 16, 2023

(51) Int. Cl. H01L 21/02; H01L 29/786

(52) U.S. Cl. CPC H01L 21/0228; H01L 21/02164; H01L 21/02189; H01L 21/02274; H01L 29/786

(57) ABSTRACT

Embodiments of the disclosure relate to articles and transistor structures and methods of preparation and use thereof, including a substrate and an amorphous oxide film overlaying at least a portion of the substrate, where the amorphous oxide film includes a first oxide and a second oxide. The first oxide can include zirconium oxide (ZrO₂), hafnium oxide (HfO₂) or a combination thereof, the second oxide can include silicon dioxide (SiO₂), aluminum oxide (Al₂O₃), nitric oxide (NO) or combinations thereof. The amorphous oxide film can conformal and have a porosity of less than about 1% and may have a dielectric constant (k) of about 8 to about 28.

### CLAIM OF PRIORITY

This application is a National Stage of International Application No. PCT/US21/28711, filed Apr. 22, 2021, which is incorporated by reference herein.

### TECHNICAL FIELD

Embodiments of the present disclosure relate to films and articles having a high dielectric constant suitable for display devices. The films and articles may be formed of an amorphous oxide, for example, a first oxide that is doped with a second oxide. Also described are methods of preparation and use thereof.

### BACKGROUND

Display devices are used for a wide range of electronic applications such as mobile devices (i.e., phones, tablets, laptops, virtual reality, augmented reality), televisions, monitors, media players, e-book readers and the like. Display devices are designed for producing a desired image by controlling the light emitted from each pixel using individual transistors of a micro/nanoscale. By adjusting the amount of light transmitted through substrates, the light and image intensity, quality and power consumption may be efficiently controlled. A variety of different display devices, such as active matrix liquid crystal display (AMLCD) or active matrix organic light emitting diodes (AMOLED), may be employed as light sources for display. In the manufacturing of display devices, an electronic device with smaller size, higher electron mobility, lower leakage current and higher breakdown voltage, would allow more pixel area for light transmission and integration of circuitry, resulting in a brighter display, higher overall electrical efficiency, faster response time and higher resolution displays.

Insulating materials with higher dielectric constants may provide enhanced electrical performance for modern devices in a display system (e.g., larger capacitance, higher on-current, reduced hysteresis, improved hump effect and less short-channel effect, etc.). These high-k dielectric films are not only suitable as high-performance storage capacitors due to larger dielectric constant, but may also serve as ideal gate insulators (GI) to provide high on-current and reduce hump-effect/short-channel effect, as well as excellent barrier layers as a result of their high density. The high-k dielectrics also allow further scaling of backplane thin-film-transistors (TFTs), in order to meet the increasingly demanding resolution specifications for display devices (e.g., >800 ppi). With only limited areas remaining in the display devices on which to form capacitors to increase electrical performance, the more advanced high-k dielectrics become, next-generation devices may benefit from a higher pixel per inch (PPI), and replace conventional dielectrics (e.g., silicon dioxide) in various applications such as TFT storage capacitors (Cst), gate insulators (GI) and hydrogen barrier layers.

### SUMMARY

According to one or more embodiments, disclosed herein is an article, comprising a substrate; and an amorphous oxide film overlaying at least a portion of the substrate, wherein the amorphous oxide film comprises a first oxide and a second oxide, wherein the first oxide comprises zirconium oxide (ZrO₂), hafnium oxide (HfO₂) or a combination thereof, wherein the second oxide comprises silicon dioxide (SiO₂), aluminum oxide (Al₂O₃), nitric oxide (NO) or combinations thereof, wherein the amorphous oxide film is conformal and comprises a porosity of less than about 1%, and wherein the amorphous oxide film comprises a dielectric constant (k) of about 8 to about 28.

In further embodiments, disclosed herein is a transistor structure, comprising a gate; a source; a drain; and an amorphous oxide film separating the gate from at least one of the source or the drain, wherein the amorphous oxide film comprises a first oxide and a second oxide, wherein the first oxide comprises zirconium oxide (ZrO₂), hafnium oxide (HfO₂) or a combination thereof, wherein the second oxide comprises silicon dioxide (SiO₂), aluminum oxide (Al₂O₃), nitric oxide (NO) or combinations thereof, wherein the amorphous oxide film comprises a porosity of less than about 1%, and wherein the amorphous oxide film comprises a dielectric constant (k) of about 8 to about 28.

In yet further embodiments, disclosed herein is a method of forming an amorphous oxide film, comprising performing a plasma-enhanced atomic layer deposition (ALD) process to form an amorphous oxide film comprising a first oxide and a second oxide, wherein the first oxide comprises ZrO₂, HfO₂ or a combination thereof, wherein the second oxide comprises SiO₂, Al₂O₃, NO, or combinations thereof, wherein the amorphous oxide film comprises a dielectric constant (k) of about 8 to about 28, and wherein performing the plasma-enhanced ALD process comprises: performing one or more ALD deposition super-cycles, each ALD deposition super-cycle comprising: performing one or more first ALD deposition cycles to deposit a first oxide layer of the first oxide; and performing one or more second ALD deposition cycles to deposit a second oxide layer to form the amorphous oxide layer of the second oxide.

### BRIEF DESCRIPTION OF THE DRAWINGS

The present disclosure is illustrated by way of example, and not by way of limitation, in the figures of the accompanying drawings in which like references indicate similar elements. It should be noted that different references to “an” or “one” embodiment in this disclosure are not necessarily to the same embodiment, and such references mean at least one.

FIG. 1 shows an amorphous oxide film in accordance with one or more embodiments of the present disclosure.

FIG. 2 shows a sectional view of a processing chamber that may be used to deposit an amorphous oxide film in accordance with one or more embodiments of the present disclosure.

FIG. 3A is a cross sectional view of a display device structure with an amorphous oxide film having a high dielectric constant in accordance with one or more embodiments of the present disclosure.

FIG. 3B is a cross sectional view of a display device structure having an amorphous oxide film having a high dielectric constant in accordance with one or more embodiments of the present disclosure.

FIG. 4 is a deposition process in accordance with an atomic layer deposition technique for depositing an amorphous oxide film or article in accordance with one or more embodiments of the present disclosure.

FIG. 5 is a flow chart for a method of forming an amorphous oxide film on a surface in accordance with one or more embodiments of the present disclosure.

FIG. 6 is a flow chart for a method of forming an amorphous oxide film on a surface in accordance with one or more embodiments of the present disclosure.

FIG. 7 is a flow chart for a method of forming an amorphous oxide film on a surface in accordance with one or more embodiments of the present disclosure.

FIG. 8A is a flow chart for a method of forming an amorphous oxide film having various ratios of a first component (e.g., an oxide, a metal, an element) to a second component (e.g., an oxide, a metal, an element) within the film in accordance with one or more embodiments of the present disclosure.

FIG. 8B is a cross sectional view of a substrate with a multi-layer amorphous oxide film disposed thereon in accordance with one or more embodiments of the present disclosure.

FIG. 8C is a cross sectional view of a substrate with an amorphous oxide film having a gradient of a first oxide and a second oxide disposed thereon in accordance with one or more embodiments of the present disclosure.

FIG. 9 is an x-ray diffraction spectrum showing the crystal structure of metal oxide films having varying molar ratios of a first component and a second component.

FIG. 10 is a chart showing capacitance-voltage hysteresis curves for samples having different compositions of amorphous oxides deposited on silicon substrates.

FIG. 11 is a chart showing the dielectric constant as a function of metal oxide film composition in accordance with one or more embodiments of the present disclosure.

FIG. 12 is a chart showing the flat band voltage (Vfb) and hysteresis for samples having different compositions of amorphous oxides deposited on silicon substrates.

### DETAILED DESCRIPTION

Embodiments of the present disclosure relate to fabrication methods and device applications of an innovative amorphous high-k metal-silicate dielectric film fabricated by atomic layer deposition (ALD). The synthesized high-k metal-oxide can be achieved by doping various elements such as Silicon (Si), Aluminum (Al) or Nitrogen (N) into High-k dielectric films such as Zirconium Oxide (ZrO₂) or Hafnium Oxide (HfO₂) through an ALD super-cycle process. The high-k metal oxide film features excellent tunability and superior electrical performance, suitable for various applications in the display industry. The methods of its preparation, characterization and device performance evaluation are also described thereof.

Disclosed are amorphous oxide films and/or articles deposited and/or grown by atomic layer deposition (ALD), for example, plasma enhanced (PE) ALD. The amorphous oxide film may be comprised of a bulk or first oxide material (e.g., ZrO₂, HfO₂) doped with a dopant or second material (e.g., SiO₂). Such films and articles according to embodiments herein are useful for display applications as described above. However, the films discussed herein are also applicable for other types of devices, such as semiconductor devices. The amorphous oxide films and/or articles can have a high dielectric constant (e.g., greater than two times that of SiO₂ dielectric or greater than about 7.8) suitable for transistor structures for display applications and other applications. In some embodiments, the amorphous oxide films can include a bulk (also referred to as primary or first) metal oxide (e.g., ZrO₂, HfO₂), which may be doped with a dopant (also referred to as a secondary or second) metal oxide (e.g., SiO₂). Notably, the use of ZrO₂ alone can be unsuitable for GI films because ZrO₂ is oxygen deficient and will bind with oxygen from SiO₂ to form an alloy with a silicon channel of a transistor structure. In other words, ZrO₂ will form an interphase layer with the silicon channel, which affects the performance of the GI. Films and articles of pure ZrO₂ can also cause significant hysteresis voltage. The interphase layer formed by ZrO₂ with the silicon channel can accumulate significant charge and generate so-called “hot defects” in the transistor structure with the potential for shifting the flat band voltage, and can contribute to a higher hysteresis voltage. Removing the interphase layer both at the bottom and top of the film used for the GI can improve the performance of the transistor structure. Doping ZrO₂ with SiO₂ not only changes the crystallinity of the film or article to an amorphous phase, but forms a better interface with the silicon channel. Accordingly, embodiments described herein set forth a high-K gate dielectric material comprising zirconium oxide with silicon doping, which provides improved performance for the GI as compared to existing materials, such as ZrO₂. Embodiments also provide other improved materials usable for GI, which include a combination of a first oxide comprising zirconium oxide (ZrO₂), hafnium oxide (HfO₂) or a combination thereof, and a second oxide comprising silicon dioxide (SiO₂), aluminum oxide (Al₂O₃), nitric oxide (NO) or combinations thereof.

According to one or more embodiments, doping a ZrO₂ film with a SiO₂ can transform the ZrO₂ from a tetragonal/cubic crystalline phase to an amorphous phase and can increase the thermal stability of the film or article at high temperatures (e.g., above about 400° C.). In embodiments, doping the ZrO₂ with SiO₂ also reduces defects in the film or article and reduces leakage. According to one or more embodiments, the disclosure also relates to methods of forming the amorphous oxide film and/or article having a high dielectric constant fabricated by an atomic layer deposition (ALD) process. The amorphous oxide film may have a high density and low film leakage suitable for display applications and/or other applications.

Amorphous oxide high-k films and/or articles deposited by ALD according to embodiments herein may be used to replace conventional dielectric materials (e.g., comprised of SiO₂) in TFT storage capacitors (Cₛₜ) and gate insulators (GI), among other applications. A higher dielectric constant can result in a larger storage capacitance to hold a gate voltage (Vg), can result in a higher on-current resulting from a stronger electric field, can reduce variation in a threshold voltage (Vth), and can reduce hump effect and short channeling effect that causes a lag in device operation. The films and/or articles according to embodiments herein also may provide a stronger field effect as compared to traditional dielectric materials, as a GI layer effectively minimizes hysteresis in TFT switching. The high-k amorphous oxide films described herein may be fabricated with a high-performance ALD system configured to deliver superior conformality, uniformity, throughput and electrical properties on large-scale panels (e.g., 1500 mm×1850 mm). To further improve the film properties and thermal stability of, for example, ZrO₂ films and/or HfO₂ films, the films may be doped with readily-controllable SiO₂ using an ALD super-cycle method and/or other ALD deposition method as described herein. The crystallinity of the ZrO₂ and/or HFO₂ film may change from tetragonal/cubic phase to amorphous phase based on doping with silicon and/or aluminum and/or nitrogen, reducing bulk/interface defects. For GI applications in display backplane TFTs, the amorphous oxide films as disclosed herein may provide significant improvement of the device performance, including the reduction of hysteresis, off-current and hump effect.

The growth of conformal amorphous oxide doped high-k films, according to embodiments herein, may be achieved through a time sequential plasma-enhanced atomic layer deposition (PEALD) reaction. For example, an ALD super-cycle process (as described herein) that includes the deposition of a bulk metal oxide, such as ZrO₂, and a dopant metal oxide, such as SiO₂, may be performed at about 100° C. to about 800° C., 200° C. to 500° C., or any individual temperature or sub-range therein. The ALD super-cycle process may be employed to change the crystallinity of ZrO₂ or HfO₂ from the tetragonal/cubic phase to the amorphous phase, reducing defect levels in the ZrO₂ or HFO₂ bulk metal oxide while improving the ZrO₂ or HfO₂ interface with an Si substrate or other substrate (e.g., a semiconductor substrate). The SiO₂ dopant level can also be readily controlled by adjusting the numbers of ZrO₂/SiO₂ or HfO₂/SiO₂ sub-cycles within the ALD super-cycle, as discussed in detail below. The deposited film may be annealed at 100° C. to about 600° C., about 400° C. to about 450° C., or any individual temperature or sub-range therein, for about 10 min to about 60 min, about 20 min to 30 min, or any individual time or sub-range therein. In some embodiments, annealing is performed in the presence of nitrogen (N₂). In some embodiments, the annealing is performed to remove impurities for better ambient stability and electrical properties, including the dielectric constant (k), leakage current, breakdown voltage, flat band voltage shift and/or hysteresis. ALD cycles may be performed in a manner that creates alternating layers of ZrO₂ (and/or HFO₂) and SiO₂ (and/or Al₂O₃ and/or NO). In embodiments, annealing may promote diffusion between the layers (e.g., to form a single layer comprising ZrO₂ and SiO₂).

According to embodiments, there can be advantages in doping a bulk metal oxide (e.g., ZrO₂, HfO₂) with a dopant metal oxide (e.g., SiO₂) for use as a high-K dielectric material. For example, a large portion of oxygen-related bulk defects can be passivated, and the interface between the bulk metal oxide film and the substrate (e.g., Si) may be improved, which can reduce hysteresis and enhance breakdown voltage, making the metal oxide-doped amorphous bulk oxide film suitable for GI applications. Additionally, the metal oxide doping level can be controlled and a gradient doping profile is possible via a super-cycle ALD process as described herein. For example, higher SiO₂-doping levels of an ZrO₂ amorphous oxide films can improve hysteresis (ideal for an interface layer) while lowering the SiO₂ doping level may be beneficial for a higher dielectric constant (k) (i.e., suitable for the bulk film). The films and articles and methods of preparation herein provide high flexibility in adjusting the high-k film properties for a variety of applications. Another advantage is significantly improved thermal stability of the bulk metal oxide (e.g., ZrO₂, HfO₂) and the ability of the film to maintain its amorphous phase above about 450° C. for a duration of about 20 min during annealing. Furthermore, a SiO₂ doped amorphous bulk ZrO₂ film may have better ambient resistance to moisture than conventional films and maintain target film properties after a long time idling in air without any capping layer. In comparison, a crystallized (i.e., tetragonal/cubic) ZrO₂ film is susceptible to absorb/react with ambient moisture, significantly reducing its dielectric constant k and electrical properties.

The amorphous oxide films according to embodiments herein may be useful for several applications. For example, benefits of utilizing amorphous ZrO₂ high-k films with gradient SiO₂-doping in next-generation mobile TFT devices can include good film uniformity on a large-scale 1500 mm×1850 mm panel with high throughput; high conformality (>95% sidewall) and precise thickness control (Angstrom level) suitable for high density device arrays (high PPI) and 3D structures. Additional benefits include compatibility with current mobile display tech-nodes and readiness for high volume production. For GI applications, the amorphous oxide films may provide a stronger field effect and significantly reduced interface defects with improved hysteresis and less hump effect as compared to conventional GI materials, in order to increase device switching speed and operational stability. For storage capacitor (Cst) applications, using a film with a higher dielectric constant provides a larger storage capacitor to hold gate voltage (Vg) against the Vg decay due to I-off through switching TFT. For program capacitor (Cpr) applications, large capacitance compensates the Vth variation of driving TFT, with lack of compensation TFT for VR/AR applications. High-k amorphous silicate films and/or articles as disclosed herein also may reduce the area of the transistor, which can to save room for a power line. A reduced area can minimize long-range non-uniformity caused by IR-drop at a high luminance condition.

In embodiments, an amorphous high-k bulk metal oxide (e.g., ZrO₂) film with a gradient metal oxide dopant (e.g., SiO₂), may be achieved using an ALD super-cycle process as described herein. The resulting films/articles can have improved hysteresis (<100 mV) with a high k value (>12) for ZrO₂-rich films with a ZrO₂ content of >85% as compared to conventional films/articles for display devices. For even higher SiO₂-doping, leakage can be improved to <2E⁻¹⁰ A/cm² and breakdown field can be enhanced to >12 MV/cm. A SiO₂-doped ZrO₂ film shows thermal stability in annealing tests up to 450° C., as well as stronger ambient resistance in air-exposure aging tests as compared to blanket ZrO₂ films. This fabrication method is also compatible with existing integration flow for display backplane TFTs.

In embodiments, capacitance of the described amorphous oxide material may be adjusted by changing the dielectric material (e.g., increasing or decreasing an amount of an SiO₂ dopant in ZrO₂) and dimension of the dielectric layer formed between the electrodes and/or thickness of the dielectric layer. For example, when the dielectric layer is replaced with a material having a higher dielectric constant, the capacitance of the capacitor increases as well.

Advantages of high dielectric constant gate insulators for display applications include a high I-on (on-current), a stronger electric field, and reduced short channel effects/hysteresis. An amorphous high dielectric constant (high-k) gate insulator according to embodiments herein may reduce interface defects between a first oxide (e.g., zirconia) to a second oxide (e.g., SiO₂, Al₂O₃). Such amorphous high-k gate insulators may also provide passivation of O⁻ vacancy bulk defects and improvement in hysteresis, leakage and hump effects. Amorphous oxide films having a first component (e.g., an oxide, a metal, an element, ZrO₂, HfO₂ or a combination of ZrO₂ and HfO₂) doped with a second component (e.g., an oxide, a metal, an element, Si, A, N, or any combination thereof) may have improved thermal stability and resistance to moisture as compared to conventional transistor structure materials. Such films may be stable when in direct contact with silicon channels and have superior electrical stability.

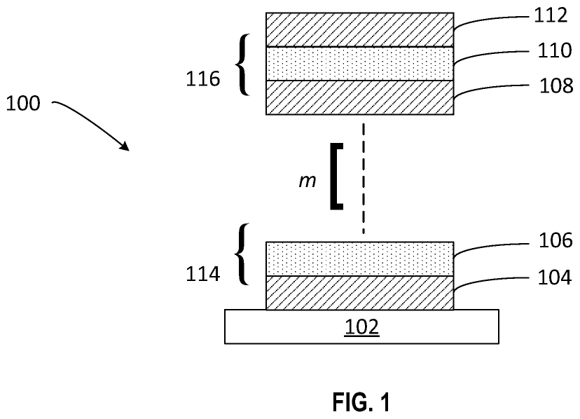

FIG. 1 shows an amorphous oxide film (e.g., a gate insulator for a capacitor) 100 in accordance with one or more embodiments of the present disclosure. According to embodiments, the film 100 may be deposited on at least one surface of a substrate 102. Suitable substrate materials include, but are not limited to, pure silicon (Si), germanium (Ge), III-V semiconductors (e.g., InP, InAs, etc.), bare glass (SiO₂) and/or combinations thereof. The at least one surface of the substrate may be the bare substrate material (e.g., Si) or may be one or more coating formed on the substrate. For example, the amorphous oxide may be deposited or otherwise formed on a metal oxide, phosphorous doped Si, boron doped Si, gallium doped Si or combinations of any two or more of the foregoing. The amorphous oxide film 100 may be deposited on the bare substrate and/or on a coating overlaying the substrate.

As shown in FIG. 1, a first oxide layer 104 may be deposited on the surface. According to embodiments, the first oxide layer 104 may be a bulk material, for example, a high-k dielectric material. Suitable high-k dielectric materials include, but are not limited to, zirconium oxide (ZrO₂), hafnium oxide (HfO₂) or a combination thereof. In embodiments, the first oxide layer 104 includes ZrO₂. In some embodiments, the first oxide layer 104 may be an adhesion material, which may be a material that suitably adheres to both the surface of the substrate as well as to a film deposited over the adhesion material. The adhesion material may be the same as a dopant material used to dope the bulk material in some embodiments. Suitable adhesion materials include, but are not limited to, SiO₂, aluminum oxide (Al₂O₃), nitric oxide (NO), magnesium oxide (MgO), titanium oxide (TiO₂) or combinations of any two or more of the foregoing. In embodiments, the first oxide layer includes SiO₂.

The amorphous oxide film 100 or article may further include a second oxide layer 106 deposited over the first oxide layer 104. The second oxide layer 106 may be a bulk material as set forth above. Suitable bulk materials include, but are not limited to, zirconium oxide (ZrO₂), hafnium oxide (HfO₂) or a combination thereof. In embodiments, the second oxide layer includes ZrO₂. In embodiments, when the first oxide layer 104 includes an adhesion material, then the second oxide layer 106 may be formed of the bulk material. In some embodiments, when the first oxide layer 104 is formed of the bulk material, the second oxide layer 106 may be formed of a dopant material. Suitable dopant materials for the second oxide layer include, but are not limited to, silicon dioxide (SiO₂), aluminum oxide (Al₂O₃), nitric oxide (NO) or combinations of any two or more of the foregoing. In embodiments, the second oxide layer includes SiO₂.

The amorphous oxide film 100 or article may be deposited using atomic layer deposition (ALD), for example, plasma enhanced (PE) ALD. Each metal oxide layer 104, 106 of the amorphous oxide film 100 or article may be deposited by at least one ALD cycle, where each ALD cycle is a set of two half reactions including a first half reaction of adsorption of a metal and a second half reaction of reaction of an oxygen reactant with the adsorbed metal. A set of the two metal oxide layers 104, 106 each deposited by at least one ALD cycle may collectively be referred to as a super-cycle layer 114. For example, the deposition of the first oxide layer 104 of a dopant material followed by the deposition of the second oxide layer 106 of a bulk material results in a super-cycle layer 114. The first oxide layer 104 may be deposited by x first ALD cycles and the second oxide layer 106 may be deposited by y second ALD cycles and the resulting super cycle layer 114 would be the sum of the x+y layers, where x and y are each independently an integer of at least 1. For example, about 1 to about 40 cycles of the dopant material (e.g., SiO₂) may be deposited and about 20 to about 200 cycles of the bulk material (e.g., ZrO₂) may be deposited in a super cycle. Each metal oxide layer 104, 106 deposited in a super-cycle may have a thickness of about 1 Å to about 1000 Å, about 1 Å to about 600 Å, about 1 Å to about 50 Å, about 1 Å to about 25 Å, about 1 Å to about 10 Å, or any individual thickness or sub-range within these ranges. In embodiments, the amorphous oxide coating has a thickness of at least about 5 Å to about 3000 Å. The deposited metal oxide layers 104, 106 may be suitably thin so that the layers 104, 106 grow into each other, that is, so that the two metal oxide layers 104, 106 combine and/or mix to form a doped metal oxide layer.

To build the thickness of the amorphous oxide film 100 or article, a plurality of super-cycles may be deposited as a stack of layers 114, 116. In the embodiment shown in FIG. 1, there may be m super-cycle layers between super-cycle layers 114, 116, where m is a decimal of at least 0.5, or m is 0.5 to 100.0, 1.0 to 50.0, 5.0 to 25.0, or any individual value or sub-range within these ranges. In embodiments, the total number of super-cycle layers (including 114, 116) may be represented by m. In embodiments, a third oxide layer 108 deposited as part of super-cycle layer 116 may be the same as the first oxide layer 104. According to embodiments, the third oxide layer 108 may be a bulk material, for example, a high-k dielectric material, a low-k dielectric material and/or a conventional semiconductor oxide material. Suitable high-k dielectric materials include, but are not limited to, zirconium oxide (ZrO₂), hafnium oxide (HfO₂) or a combination thereof. Suitable low-k dielectric materials include, but are not limited to, porous SiO₂ films, SiCON compound dielectrics, SiC films or combinations thereof. Conventional dielectric materials include, but are not limited to, SiO₂, GeOₓ, SiNₓ or combinations thereof. In embodiments, the third oxide layer 108 includes ZrO₂. In some embodiments, the third oxide layer 108 may be a dopant material. Suitable dopant materials include, but are not limited to, silicon, SiO₂, aluminum, aluminum oxide (Al₂O₃), nitrogen, nitric oxide (NO), or combinations of any two or more of the foregoing. In embodiments, the third oxide layer 108 may include SiO₂.

The amorphous oxide film 100 or article may further include a fourth oxide layer 108 deposited over the third oxide layer 106 to form super-cycle layer 116. The fourth oxide layer 110 may be a bulk material as set forth above. Suitable bulk materials include, but are not limited to, zirconium oxide (ZrO₂), hafnium oxide (HfO₂) or a combination thereof. In embodiments, the fourth oxide layer 110 may be ZrO₂. In embodiments, the fourth oxide layer 110 may differ from the third oxide layer 108. In some embodiments, when the third oxide layer 104 is formed of the bulk material, the fourth oxide layer 104 may be formed of a dopant material. Suitable dopant materials for the fourth oxide layer include, but are not limited to, silicon dioxide (SiO₂), aluminum oxide (Al₂O₃), nitric oxide (NO) or combinations of any two or more of the foregoing. In embodiments, the fourth oxide layer includes SiO₂. Once deposited, the amorphous oxide film 100 may have a dielectric constant of about 8 to about 34, about 10 to about 25, about 15 to 20, or any individual value or sub-range within these ranges.

According to embodiments, a molar ratio of a first component in the first oxide layer 104 to a second component in the second oxide layer 106, or of the first component in the third oxide layer 108 to the second component in the fourth oxide layer may be about 1:100 to about 100:1, about 1:10 to about 10:1, about 3:20 to about 20:3, 1:5 to 5:1, or any individual ratio or sub range within these ranges. Similarly, the resulting super-cycle layers 114, 116 (i.e., containing a mixture of the first and second oxides) independently may include a molar ratio of a first component to a second component of about 1:100 to about 100:1, about 1:10 to about 10:1, about 3:20 to about 20:3, 1:5 to 5:1, or any individual ratio or sub range within these ranges. For example, the amorphous oxide layer may include X-Y mol % of ZrO₂ and A-B mol % of SiO₂ in an embodiment. In one or more embodiments, where the first oxide is SiO₂ and the second oxide is ZrO₂, the two metal oxides can be present at a molar ratio of about 1:1. Such films are in an amorphous phase and have a dielectric constant that is higher than that of SiO₂ alone. The properties of such complex amorphous oxide films that include a combination of at least two different metal oxides can be better than those for silicon nitrite films commonly used for transistor structures. Additionally, SiO₂-rich films/articles can be a good replacement for nitrite films, especially for GI applications.

According to embodiments, the amounts of a first oxide and a second oxide in a first super-cycle layer may differ from the amounts of the first oxide and the second oxide in a second super-cycle layer. The amounts in the second super-cycle layer may differ from the amounts of the first oxide and the second oxide in a third super-cycle layer, and so on. For example, in one or more super-cycle layer closest to the substrate 102 the first oxide and the second oxide may be present in first amounts. In one or more second super-cycle layer, for example, in the middle of the amorphous oxide film 100, the first oxide and the second oxide may be present in second amounts. In one or more super-cycle layer near the surface of the amorphous oxide coating 100 (e.g., super-cycle layer 116), the first oxide and the second oxide may be present in third amounts. Similarly, the first oxide and the second oxide may be present at a first ratio in one or more super-cycle layers 114 closest to the substrate 102, at a second ratio in one or more super-cycle layers in the middle of the amorphous oxide coating 100, and at a third ratio in one or more super-cycle layer 116 near the surface of the amorphous oxide coating 100. In some embodiments, the first ratio is approximately equal to the third ratio. In one example embodiment, the amorphous oxide film has a first ratio of 10 to 40 near an interface with substrate 102, a second ratio of 40 to 10 near a middle of the amorphous oxide film, and a third ratio of 10 to 40 near a top of the amorphous oxide film. It should be noted that the foregoing discussion of a first oxide and a second oxide is for illustrative purposes only. As set forth above, the super-cycle layers may not include the same two metal oxides. For example, super-cycle layer 114 may include metals M₁ and M₂, a super-cycle layer within the m region depicted in FIG. 1 may include M₁ and M₃, M₂ and M₃, M₃ and M₄, and super-cycle layer 116 may include any one of M₁ to M₄, or M₅ and M₆ or any combination of the foregoing.

According to embodiments, the amorphous oxide film 100, which may be deposited by ALD (e.g., PEALD), may be conformal. The term “conformal” as used herein refers to the thickness of a deposited film or layer as being relatively uniform across the surface of a substrate (so that, for example, the thickest regions of the coating are no greater than about 3× the thickness of the thinnest regions), so that the surface shape of the film coated substrate resembles that of the underlying substrate surface. Conformality may be determined by transmission electron spectroscopy (TEM) having a resolution of 10 nm or below. Lower resolution techniques cannot distinguish conformal from non-conformal coatings at this scale. The desired substrate surface is preferably coated substantially without pinholes or defects. The amorphous oxide film 100 may have a porosity of less than about 1%, less than about 0.1%, or about zero porosity as measured by Tunneling Electron Microscopy (TEM). The electrical properties including dielectric constant, leakage current, breakdown voltage, flatband voltage and/or hysteresis can be characterized by a mercury probe or electrical probe station at room temperature and ambient pressure.

According to one or more embodiments, the second component may be a dopant, wherein the amorphous oxide film comprises the second component in an amount of at least about 1 mol % to less than about 50 mol %. In one or more embodiments, the first oxide comprises ZrO₂, wherein the second oxide comprises SiO₂, and wherein the SiO₂ is present in an amount of at least about 9 mol % to less than about 50 mol %. The amorphous oxide film may have a thickness of at least about 200 Å to about 2,000 Å. Additionally, the amorphous oxide film or article can have a first ratio of the first component to the second component within a first thickness of the amorphous oxide film, a second ratio of the first component to the second component within a second thickness of the amorphous oxide film, and a third ratio of the first component to the second component within a third thickness of the amorphous oxide film.

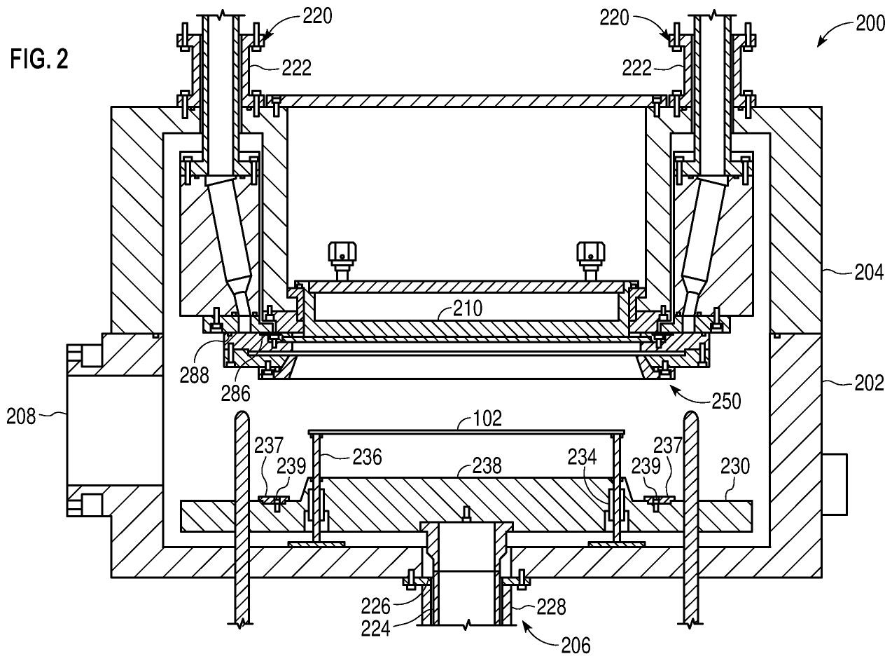

FIG. 2 is a schematic cross sectional view of an atomic layer deposition (ALD) chamber 200 that may be used to deposit an amorphous oxide film as described herein. The ALD deposition process may be utilized to form a dielectric layer, such as an insulating layer, a gate insulating layer, an etch stop layer, an interlayer insulator, a dielectric layer for capacitor or a passivation layer in display devices as described herein. The chamber 200 may include a chamber body 202, a lid assembly 204, a substrate support assembly 206, and a process kit 250. The lid assembly 204 may be disposed on the chamber body 202, and the substrate support assembly 206 may be at least partially disposed within the chamber body 202. The chamber body 202 may include a slit valve opening 208 formed in a sidewall thereof to provide access to the interior of the processing chamber 200, In some embodiments, the chamber body 202 includes one or more apertures in fluid communication with a vacuum system (e.g., a vacuum pump). The apertures provide an egress for gases within the chamber 200. The vacuum system may be controlled by a process controller to maintain a pressure within the ALD chamber 200 suitable for ALD processes. The lid assembly 204 may include one or more differential pumps and purge assemblies 220. The differential pump and purge assemblies 220 may be mounted to the lid assembly 204 with bellows 222. The bellows 122 allow the pump and purge assemblies 220 to move vertically with respect to the lid assembly 204 while still maintaining a seal against gas leaks. When the process kit 250 is raised into a processing position, a compliant first seal 286 and a compliant second seal 288 on the process kit 250 are brought into contact with the differential pump and purge assemblies 220. The differential pump and purge assemblies 220 are connected with a vacuum system (not shown) and maintained at a low pressure.

As shown in FIG. 2, the lid assembly 204 may include a RF cathode 210 that can generate a plasma of reactive species within the chamber 200 and/or within the process kit 250. The RF cathode 210 may be heated by electric heating elements (not shown), for example, and cooled by circulation of cooling fluids, for example. Any power source capable of activating the gases into reactive species and maintaining the plasma of reactive species may be used. For example, RF or microwave (MW) based power discharge techniques may be used. The activation may also be generated by a thermally based technique, a gas breakdown technique, a high intensity light source (e.g., UV energy), or exposure to an x-ray source.

The substrate support assembly 206 can be at least partially disposed within the chamber body 202. The substrate support assembly 206 can include a substrate support member or susceptor 230 to support a substrate 102 for processing within the chamber body. The susceptor 230 may be coupled to a substrate lift mechanism (not shown) through a shaft 224 or shafts 224 which extend through one or more openings 226 formed in a bottom surface of the chamber body 202. The substrate lift mechanism can be flexibly sealed to the chamber body 202 by a bellows 228 that prevents vacuum leakage from around the shafts 224. The substrate lift mechanism allows the susceptor 230 to be moved vertically within the ALD chamber 200 between a lower robot entry position, as shown, and processing, process kit transfer, and substrate transfer positions. In some embodiments, the substrate lift mechanism moves between fewer positions than those described.

In some embodiments, the substrate 102 may be secured to the susceptor using a vacuum chuck (not shown), an electrostatic chuck (not shown), or a mechanical clamp (not shown). The temperature of the susceptor 230 may be controlled (by, e.g., a process controller) during processing in the ALD chamber 200 to influence temperature of the substrate 102 and the process kit 250 to improve performance of the ALD processing. The susceptor 230 may be heated by, for example, electric heating elements (not shown) within the susceptor 230. The temperature of the susceptor 230 may be determined by pyrometers (not shown) in the chamber 200, for example.

As shown in FIG. 2, the susceptor 230 can include one or more bores 234 through the susceptor 230 to accommodate one or more lift pins 236. Each lift pin 236 is mounted so that the lift pin 236 may slide freely within a bore 234. The support assembly 206 is movable such that the upper surface of the lift pins 236 can be located above the substrate support surface 238 of the susceptor 230 when the support assembly 206 is in a lower position. Conversely, the upper surface of the lift pins 236 is located below the upper substrate support surface 238 of the susceptor 230) when the support assembly 206 is in a raised position. When contacting the chamber body 202, the lift pins 236 push against a lower surface of the substrate 102, lifting the substrate off the susceptor 230. Conversely, the susceptor 230 may raise the substrate 102 off of the lift pins 236.

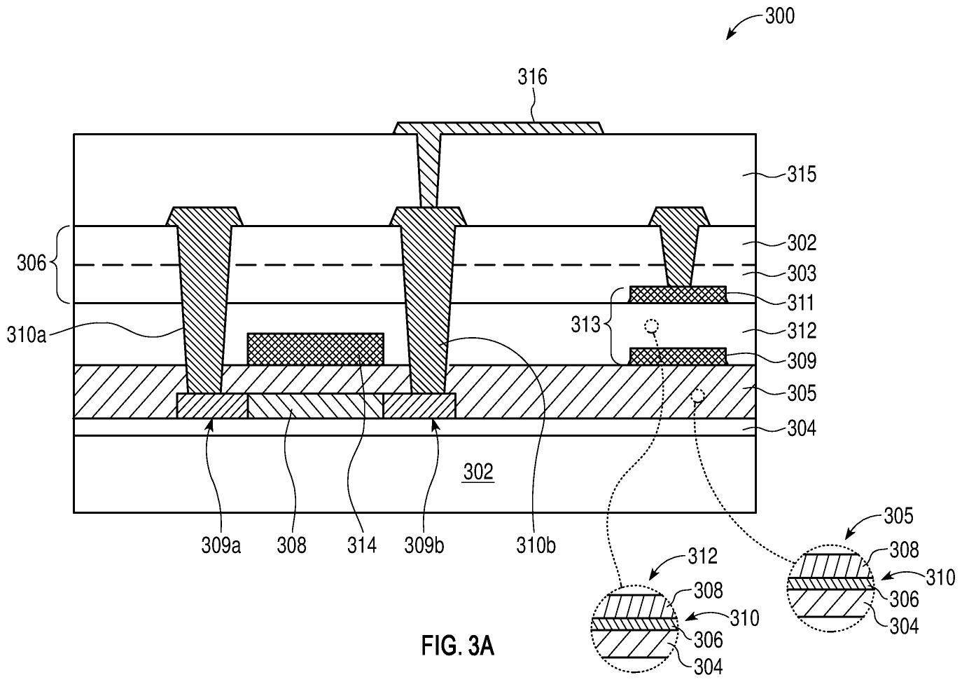

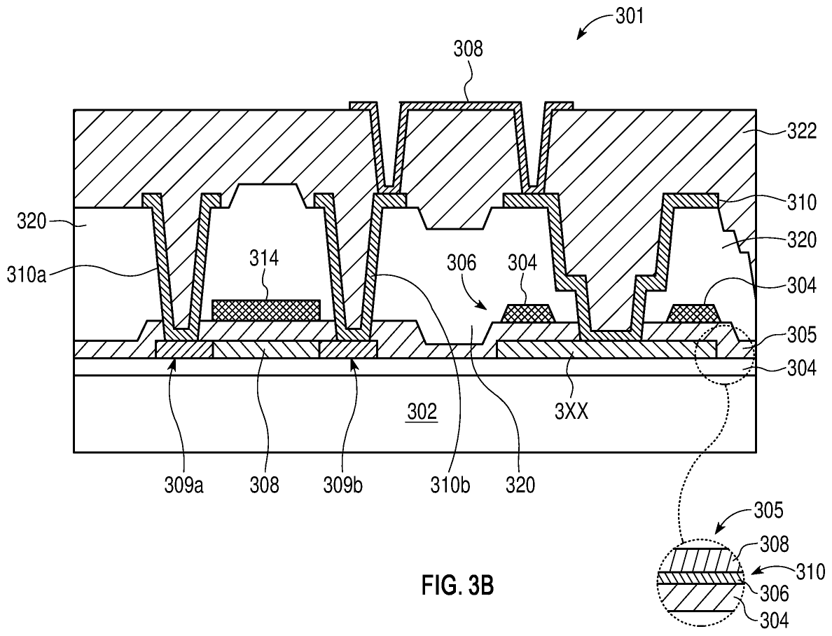

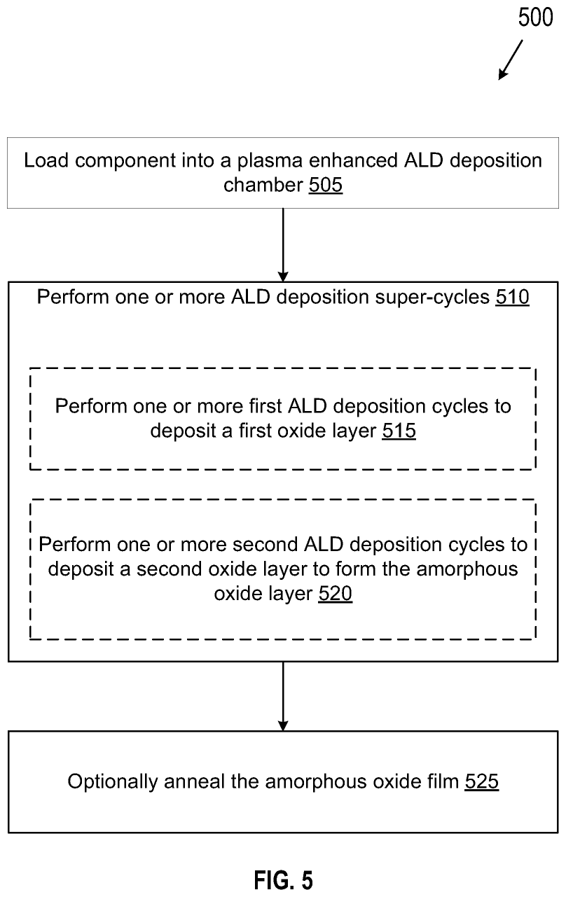

FIG. 3A depicts an example of a TFT device structure 300 having an amorphous oxide film in the TFT device structure 300 to form a capacitor, or a gate insulating layer, or other suitable insulating layers. A portion of the exemplary TFT device structure 300 is depicted in FIG. 3A formed on the substrate 302. The TFT device structure 300 comprises a low temperature polysilicon (LTPS) TFT for OLED device. The LTPS TFT device structures 300 are MOS devices built with a source region 309a, channel region 308, and drain region 309b formed on the optically transparent substrate 302 with or without an optional insulating layer 304 disposed thereon. The source region 309a, channel region 308 and drain region 309b are generally formed from an initially deposited amorphous silicon (a-Si) layer that is typically later thermal or laser processed to form a polysilicon layer. The source, drain and channel regions 309a, 308, 309b can be formed by patterning areas on the optically transparent substrate 302 and ion doping the deposited initial a-Si layer, which is then thermally or laser processed (e.g., an Excimer Laser Annealing process) to form the polysilicon layer. A gate insulating layer 305 (e.g., the insulating layer or the hybrid film stack 310 with high dielectric constant optionally formed by the process 500 of FIG. 5) may be then deposited on top of the deposited polysilicon layer(s) to isolate a gate electrode 314 from the channel region 308, source region 309a and/or drain regions 309b. The gate electrode 314 is formed on top of the gate insulating layer 305. The gate insulating layer 305 is also commonly known as a gate oxide layer, A capacitor layer 312 (e.g., may also be the insulating layer or the hybrid film stack 310 formed by the process 500 of FIG. 5) and device connections are then made through the insulating material to allow control of the TFT device. As indicated by the circles in FIG. 3A, the gate insulating layer 305 and the capacitor layer 312 in the TFT device structure 300 may also be fabricated by the amorphous oxide film 310 with high dielectric constant as well as the low film leakage including the first layer 304 and the second layer 308 and the interface layer 306 formed therebetween. In the embodiment wherein the optional insulating layer 304 is present, the first layer 304 comprising the silicon containing layer may be eliminated as the optional insulating layer 304 and the first layer 304 may both be formed from a silicon material.

The TFT device structure 300 of FIG. 3A is just partially formed for ease of description and explanation regarding to where the hybrid film stack 310 may be utilized in some locations in the device structure 300 utilized to form either the gate insulating layer 305 or the capacitor layer 312, or both, in the device structure 300.

After the capacitor layer 312 is formed, an interlayer insulator 306 may be formed on the capacitor layer 312. The interlayer insulator 306 may be any suitable dielectric layer, such as silicon oxide or silicon nitride materials. The interlayer insulator 306 may be in form of a single layer formed on the capacitor layer 312. Alternatively, the interlayer insulator 306 may be in form of multiple layers for different device specifications. In the example depicted in FIG. 3A, the interlayer insulator 306 includes a first dielectric layer 302 of silicon nitride formed on a second layer 303 of a silicon oxide layer. Subsequently, a source-drain metal electrode layer 310a, 310b is then deposited, formed and patterned in the interlayer insulator 306, the capacitor layer 312 and the gate insulating layer 305 electrically connected to the source region 309a and drain regions 309b.

After the source-drain metal electrode layer 310a, 310b is patterned, planarization layer 315 is then formed over the source-drain metal electrode layer 310a, 310b. The planarization layer 315 may be fabricated from polyimide, benzocyclobutene-series resin, spin on glass (SOG) or acrylate. The planarization layer 315 is later patterned to allow a pixel electrode 316 to be formed on and filled in the planarization layer 315, electrically connecting to the source-drain metal electrode layer 310a, 310b.

In this example depicted in FIG. 3A, the capacitor layer 312 is formed on the gate electrode 314 extending to a capacitor structure 313 (e.g., a MIM (metal-insulating-metal) structure) formed between an upper electrode 311 and a lower electrode 309. The upper electrode 311 may be laterally coupled to the source-drain metal electrode layer 310a, 310h while the lower electrode 309 may be laterally coupled to the gate electrode 314, or other suitable electrodes in the device structure 300. The capacitor structure 313 formed in the device structure 300 may be a storage capacitor that may improve the display device electrical performance. It is noted that the capacitor structure 313 may be formed in any location suitable in the device structure 300 for different device performance targets.

In another example depicted in FIG. 3B a capacitor structure 322, similar to the capacitor structure 313 depicted in FIG. 3A, may be formed with different dimensions and/or profiles of the hybrid film stack 310 serving as a capacitor layer 320 formed between the upper electrode 311 and the lower electrode 309. Unlike the capacitor layer 312 shown in FIG. 3A that extends from the area above the gate electrode 314 to the area between the upper and the lower electrode 311, 309, the capacitor layer 320 depicted in FIG. 3B is formed substantially in the area between the upper and the lower electrodes 311, 309. Thus, a regular interlayer insulator 324 comprising silicon oxide or silicon nitride may be formed on the gate insulting layer 305 surrounding the capacitor structure 322, The hybrid film stack 310 formed as the capacitor layer 320 in the capacitor structure 322 may have a bottom surface in contact with the lower gate insulating layer 305. The interlayer insulator 324 may be in a single layer form, as depicted in FIG. 3B, or in multiple layer form.

It is noted that the hybrid film stack 310 formed, for example, by the process 500 may be utilized to form the capacitor layer 320, gate insulating layer 305, as indicated in the circles of FIG. 3B, a passivation layer or any other suitable layers that benefit from insulating materials in the TFT device structures 300 including LTPS TFT for LCD or OLED TFT.

It is noted that the upper electrode 311 and the lower electrode 309 utilized to form the capacitor structures 322, 313 may also be pixel electrodes and/or common electrodes.

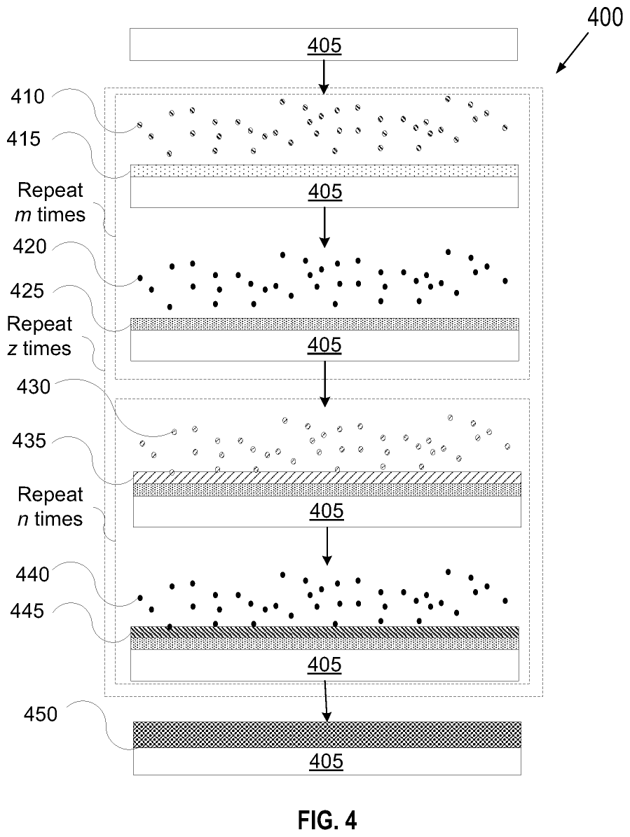

Referring to FIG. 4, an amorphous oxide film according to embodiments herein may be deposited onto at least a portion of a surface of a substrate 405 using ALD For ALD, either adsorption of a precursor onto a surface or a reaction of a reactant with the adsorbed precursor may be referred to as a “half-reaction” of an ALD cycle. During a first half reaction, a precursor is pulsed onto at least a portion of the surface of the substrate 405 (including onto any existing coatings, films or structures on the surface) for a period of time sufficient to allow the precursor to fully adsorb onto the surface. The adsorption is self-limiting as the precursor will adsorb onto a finite number of available sites on the surface, forming a uniform continuous adsorption layer on the surface. Any sites that have already adsorbed with a precursor will become unavailable for further adsorption with the same precursor unless and/or until the adsorbed sites are subjected to a treatment that will form new available sites on the uniform, continuous adsorption layer. Exemplary treatments may be plasma treatment, treatment by exposing the uniform, continuous adsorption layer to radicals, or introduction of a different precursor able to react with the most recent uniform continuous layer adsorbed onto the surface. In some implementations, two or more precursors may be injected together and adsorbed onto the surface. Any excess precursor left in the ALD reaction chamber may be pumped out until an oxygen-containing reactant is injected to react with the adsorbates to form a solid single phase or multi-phase layer. This fresh layer is ready to adsorb precursors in the next ALD cycle.

As shown in FIG. 4, at least a portion of a surface of substrate 405 may be contacted with a first precursor 410 comprising at least one metal. The surface may be contacted with the first precursor 410 for a first duration until at least a portion of surface of article 405 is fully adsorbed with the first precursor 410 to form an adsorption layer 415. This may be referred to as a first half reaction of an ALD cycle. The first precursor 410 may be a Zr precursor, a Hf precursor or a combination thereof. Suitable zirconium precursors include, but are not limited to, zirconium (IV) bromide, zirconium (IV) chloride, zirconium (IV) tert-butoxide, tetrakis(diethylamido)zirconium (IV), tetrakis(dimethylamido)zirconium (IV), tetrakis(ethylmethylamido)zirconium (IV) (TEMAZ), or combinations thereof. Suitable hafnium precursors include, but are not limited to, bis(trimethylsilyl)amidohafnium(IV) chloride, dimethylbis(cyclopentadienyl)hafnium(IV), dimethylbis(cyclopentadienyl)hafnium(IV), hafnium(IV) tert-butoxide, hafnium isopropoxide isopropanol adduct, tetrakis(diethylamido)hafnium(IV), tetrakis(dimethylamido)hafnium(IV), tetrakis(ethylmethylamido)hafnium(IV) or combinations thereof.

Alternatively, the first precursor 410 may be a Si precursor, an Al precursor, an N precursor or a combination of any two or more of the foregoing. Suitable silicon precursors include, but are not limited to, di-isopropylaminosilane (DIPAS), silane, dichlorosilane, 2, 4, 6, 8-tetramethylcyclotetrasiloxane, dimethoxydimethylsilane, disilane, methylsilane, octamethylcyclotetrasiloxane, tris(isopropoxy)silanol, tris(tert-butoxy)silanol, tris(tert-pentoxy)silanol or combinations thereof. Suitable aluminum precursors include, but are not limited to, trimethyl aluminum (TMA), diethylaluminum ethoxide, tris(ethylmethylamido)aluminum, aluminum sec-butoxide, aluminum tribromide, aluminum trichloride, triethylaluminum, triisobutylaluminum, trimethylaluminum, tris(diethylamido)aluminum, or combinations thereof. Suitable nitrogen precursors include, but are not limited to, N₂, NH₃, or N₂H₄, C₁-C₁₀ alkylhydrazine compounds or combinations thereof.

The deposition of nitrogen as a dopant may be achieved at a higher temperature than the deposition of silicon and/or aluminum. Moreover, the use of N as a dopant eliminates possible metal contamination resulting from the use of a metal-containing dopant. N-related by-products may also be readily cleaned. A film or article having Al₂O₃ as a dopant may benefit from a SiO₂ capping layer or other structure for protecting the Al₂O₃ during cleaning of the resulting film and/or article. As with SiO₂, an Al₂O₃ dopant can convert a bulk material such as ZrO₂ or HfO₂ from a crystalline phase to an amorphous phase and provides good temperature stability during annealing at temperatures of about 400° C. or higher.

Subsequently, substrate 405 may be introduced to a reactant 420 to react with the adsorption layer 415 to grow a solid layer 425 (e.g., so that the layer 425 is fully grown or deposited, where the terms “grown” and “deposited” may be used interchangeably herein). The first reactant 420 may be oxygen, water vapor, ozone, oxygen radicals, or other oxygen source. Layer 425 may be a single-layer metal oxide (e.g., ZrO₂, SiO₂).

Layer 425 may be uniform, continuous and conformal. The coating is porosity free (e.g., have a porosity of zero) or as an approximately zero porosity in embodiments (e.g., a porosity of 0% to 0.01%). Layer 425 may have a thickness of less than one atomic layer to a few atoms in some embodiments after a single ALD deposition cycle. Some metalorganic precursor molecules are large. After reacting with the reactant 420, large organic ligands may be gone, leaving much smaller metal atoms. One full ALD cycle (e.g., that includes introduction of precursor 410 followed by introduction of reactant 420) may result in the formation of a layer with an average thickness less than a single unit cell.

Multiple full ALD deposition cycles may be implemented to deposit a thicker layer 425, with each full cycle (e.g., including introducing precursor 410, flushing, introducing reactant 420, and again flushing) adding to the thickness by an additional fraction of an atom to a few atoms. As shown, up to m full cycles may be performed to grow the layer 425, where m is an integer of at least one. In some embodiments, a layer of an amorphous oxide film can be grown on substrate 405 as layer 425 via a full cycle or sequence of cycles.

In embodiments, after layer 425 having a target thickness is formed, further ALD process operations are performed to deposit a layer 435 comprising a metal oxide different from the metal oxide in layer 425. For example, after reactant 420 is evacuated from the ALD reaction chamber, at least a portion of layer 425 may be contacted with a second precursor 430 comprising at least one metal different from the at least one metal in first precursor 410 and layer 425. Layer 425 may be contacted with the second precursor 430 for a duration until at least the portion of layer 425 is fully adsorbed with the second precursor 430 to form a partial adsorption layer 435. If the first precursor 410 is a Zr precursor, a Hf precursor or a combination thereof as described above, then the second precursor 430 may be a Si precursor, an Al precursor, an N precursor or a combination of any two or more of the foregoing as described above. Alternatively, if the first precursor 420 is a Si precursor, an Al precursor, an N precursor or a combination of any two or more of the foregoing as described above, then the second precursor 430 may be a Zr precursor, a Hf precursor or a combination thereof as described above.

Subsequently, substrate 405 may be introduced to a reactant 440 to react with partial adsorption layer 435 to grow layer 445 (e.g., so that layer 445 is fully grown). The deposition of the first oxide layer 425 followed by the deposition of the second oxide layer 435 of may be considered a super-cycle. The reactant 440 may be the same as reactant 420, or may be different. In embodiments, reactant 440 may be oxygen, water vapor, ozone, oxygen radicals, or other oxygen source.

Multiple full ALD deposition cycles may be implemented to deposit a thicker layer 445, with each full cycle (e.g., including introducing precursor 430, flushing, introducing reactant 440, and again flushing) adding to the thickness by an additional fraction of an atom to a few atoms. As shown, up to n full cycles may be performed to grow the layer 445, where n is an integer of at least one. In some embodiments, an amorphous oxide film can be grown on substrate 405 as layer 425 via a full cycle or sequence of cycles, and then, after purging the deposition chamber, another full deposition cycle or sequence of deposition cycles can be used to grow another layer of the same metal oxide or of a different metal oxide.

One or more super-cycles may be performed, where a super-cycle includes m repetitions of flowing precursor 410, flushing, flowing reactant 420, and flushing, followed by n repetitions of flowing precursor 430, flushing, flowing reactant 440, and flushing. The values of m and/or n may change or stay the same with each super-cycle. As shown, up to z super-cycles may be performed to grow the film 450, where z is an integer of at least one. The film 450 may include an alternating sequence of layers of a first oxide (e.g., SiO₂) and a second oxide (ZrO₂), where the first oxide may interrupt crystal formation of the second oxide and/or the second oxide may interrupt crystal formation of the first oxide, resulting in the film 450 being an amorphous oxide film.

The resulting amorphous oxide film 450 may be uniform, continuous and conformal. The film 450 is porosity free (e.g., have a porosity of zero) or has an approximately zero porosity in embodiments (e.g., a porosity of 0% to 0.01%).

Film 450 may be an amorphous oxide film according to embodiments herein. Each metal oxide layer 425, 435 may have a thickness of one atomic layer to a few atoms in some embodiments. The deposited metal oxide layers 425, 435 may be suitably thin so that the layers 425, 435 grow into each other, that is, so that the two metal oxide layers 425, 435 combine and/or mix. In embodiments, the amorphous oxide film 450 may have a thickness of about 1 Å to about 100 Å, about 1 Å to about 50 Å, about 1 Å to about 25 Å, about 1 Å to about 10 Å, or any individual value or sub-range within these ranges.

In embodiments, amorphous oxide film 450 has a molar ratio of a first component (e.g., an oxide) to a second component (e.g., an oxide) of about 1:100 to about 100:1, about 1:10 to about 10:1, about 3:20 to about 20:3, 1:5 to 5:1, or any individual ratio or sub range within these ranges. In embodiments, the amorphous oxide film 450 may include a bulk metal oxide (e.g., ZrO₂) and a dopant metal oxide (e.g., SiO₂), wherein the bulk metal oxide is in excess of the dopant metal oxide.

In some embodiments, an ALD process described may be performed to deposit an adhesion layer prior to deposition of the amorphous oxide film or article. The adhesion layer can include, but is not limited to, SiO₂, Si, SiC, SiₓC_{y}O_{z}, SiₓO_{y}N_{z}, SiₓC_{y}N_{z}, Si₃N₄, other Si containing material, Al₂O₃, AlN or combinations thereof. For example, a silicon precursor may be used to deposit Si followed by an oxygen source reactant to form an SiO₂ adhesion layer.

FIG. 5 illustrates a method 500 for forming an amorphous oxide film or article according to embodiments. Method 500 may be used to deposit an amorphous oxide film as described herein on at least a portion of a surface of a substrate. The method may begin at block 505, by loading a substrate into an ALD or PEALD deposition chamber. Optionally, a deposition process is performed to deposit an adhesion layer such as a SiₓO_{y} (e.g., SiO₂) layer on the substrate. In one embodiment, method 500 includes forming an adhesive layer on a surface of the substrate, and forming the amorphous oxide film or article on the adhesive layer

At block 510, the method may include performing one or more ALD deposition super-cycles to deposit and/or form an amorphous oxide film and/or article according to embodiments herein. Performing the one or more ALD deposition super-cycles may include at block 515 performing one or more first ALD deposition cycles to deposit a first oxide layer. The first ALD deposition cycle may be repeated m times to build up the first oxide layer to a target thickness, where m is an integer of at least 1. The first oxide may include ZrO₂ deposited using a TEMAZ precursor together with N₂O at a 10 kW RF in an embodiment. The second oxide may include SiO₂ and may be deposited using a DIPAS precursor together with N₂O at a 4 kW RF in an embodiment.

At block 520, the method may further include performing one or more second ALD deposition cycles to deposit a second oxide layer to form the amorphous oxide layer. The second ALD deposition cycle may be repeated n times to deposit a desired amount of a second oxide. As set forth above, a molar ratio of the first oxide to the second oxide in the amorphous oxide film or article may be about 1:100 to about 100:1, about 1:10 to about 10:1, about 3:20 to about 20:3, 1:5 to 5:1, or any individual ratio or sub range within these ranges. In embodiments, the amount of first oxide (e.g., ZrO₂, HfO₂) in the amorphous oxide film or article may be about 50 mol % to about 91 mol %. The amount of the second oxide (e.g., SiO₂, Al₂O₃, NO) in the amorphous oxide film or article may be at least about 9 mol % to about 50 mol %.

In embodiments, the method 500 may include performing a plurality of ALD super-cycles, that is, repeating blocks 515, 520. Different numbers of ALD deposition cycles may be performed at block 515 and 520 for different super-cycles in some embodiments. This may result in a gradient of a molar ratio of the first and second oxides at different depths or regions of the amorphous oxide film. According to embodiments, the method 500 may include depositing the first oxide and the second oxide in first amounts at a first ratio in a first super-cycle layer. The method 500 may further include depositing the first oxide and the second oxide in second amounts at a second ratio in a second super-cycle layer overlaying the first super-cycle layer. The method 500 additionally may include depositing the first oxide and the second oxide in third amounts at a third ratio in a third super-cycle layer overlaying the second super-cycle layer and so on. As described with respect to FIG. 1, the resulting amorphous oxide film deposited by method 500 may have different compositions at different thicknesses of the film.

Optionally, at block 525, the method 500 includes annealing the amorphous oxide film or article or subjecting the film or article to a heat treatment to evaporate any residual gases and/or components from the surface and/or to purify the amorphous oxide film. The annealing process may also cause the first and second oxides to interdiffuse. The annealing or heat treatment may be at a temperature of about 200° C. to about 1,000° C., about 300° C. to about 800° C., about 420° C. to about 600° C., or any individual temperature or sub-range within the foregoing ranges.

In addition to using an ALD technique that includes performing one or more super-cycles to deposit a metal oxide coating containing a first oxide and a second oxide, additional ALD techniques may also be used, as set forth below.

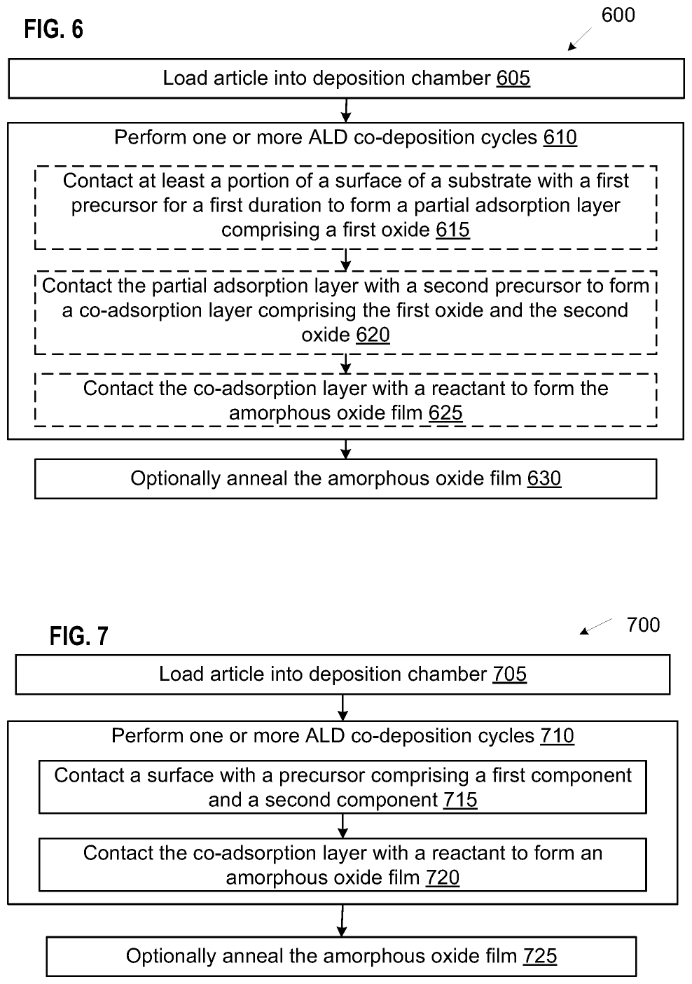

FIG. 6 illustrates a method 600 for forming an amorphous oxide film or article according to embodiments. Method 600 may be used to co-deposit metal oxides to form an amorphous oxide film or article as described herein on at least a portion of a surface of a substrate. The method 600 may begin at block 605, by loading a substrate into an ALD or PEALD deposition chamber.

Optionally, a deposition process may be performed to deposit an adhesion layer such as a SiₓO_{y} (e.g., SiO₂) layer on the substrate. In one embodiment, method 600 includes forming an adhesive layer on a surface of the substrate, and forming the amorphous oxide film or article on the adhesive layer

At block 610, the method 600 may include performing one or more ALD co-deposition cycles to deposit and/or form an amorphous oxide film and/or article according to embodiments herein. Performing the one or more ALD co-deposition cycles may include at block 615 contacting at least a portion of a surface of a substrate with a first precursor for a first duration to form a partial adsorption layer comprising a first component. At block 620, the method 600 may further include contacting the partial adsorption layer with a second precursor to form a co-adsorption layer comprising the first component and a second component. The second precursor may displace some of the adsorbed first component with the second component, resulting in an adsorption layer containing both the first component and the second component. The selection of which precursor to flow first, and the duration with which the second precursor is flowed into the deposition chamber may affect a ratio of the first component to the second component in the adsorption layer. The co-adsorption layer may then be contacted, at block 625, with a reactant for a period of time to form the amorphous oxide film. The performance of blocks 615, 620 and 625 together are an ALD cycle. The method 600 may include repeating the ALD cycle at least m times until the amorphous oxide film achieves a desired thickness.

According to embodiments, the method 600 may include depositing the first component and the second component in first amounts at a first ratio in a first co-adsorption film. The method 600 may further include depositing the first component and the second component in second amounts at a second ratio in a second co-adsorption film overlaying an oxide layer formed from the first co-adsorption film. The method 600 additionally may include depositing the first component and the second component in third amounts at a third ratio in a third co-adsorption film overlaying the second oxide layer formed from the second co-adsorption film and so on. As described with respect to FIG. 1, the resulting amorphous oxide film deposited by method 600 may have different compositions at different thicknesses of the film.

Optionally, at block 625, the method 600 includes annealing the amorphous oxide film or article or subjecting the film or article to a heat treatment to evaporate any residual gases and/or components from the surface and to purify the amorphous oxide film. The annealing or heat treatment may be at a temperature of about 200° C. to about 1,000° C., about 300° C. to about 800° C., about 420° C. to about 600° C., or any individual temperature or sub-range within the foregoing ranges.

FIG. 7 illustrates a method 700 for forming an amorphous oxide film or article according to embodiments. Method 700 may be used to co-deposit metal oxides to form an amorphous oxide film or article as described herein on at least a portion of a surface of a substrate. The method 700 may begin at block 705, by loading a substrate into an ALD or PEALD deposition chamber.

Optionally, a deposition process may be performed to deposit an adhesion layer such as a SiₓO_{y} (e.g., SiO₂) layer on the substrate. In one embodiment, method 700 includes forming an adhesive layer on a surface of the substrate, and forming the amorphous oxide film or article on the adhesive layer

At block 710, the method 700 may include performing one or more ALD co-deposition cycles to deposit and/or form an amorphous oxide film according to embodiments herein. Performing the one or more ALD co-deposition cycles may include at block 715 flowing a first precursor and a second precursor into the deposition chamber concurrently. A ratio of the first precursor to the second precursor may be based on a target molar ratio of a first oxide to a second oxide for a particular ALD cycle. At block 715, the first and second precursors contact at least a portion of a surface of a substrate to form a co-adsorption layer comprising a first component and a second component. The co-adsorption layer may then be contacted, at block 720, with a reactant for a period of time to form the amorphous oxide film including the first oxide and the second oxide. The performance of blocks 715 and 720 together are an ALD cycle. The method 700 may include repeating the ALD cycle at least m times until the amorphous oxide film achieves a desired thickness, where m is an integer of at least 1.

According to embodiments, the method 700 may include depositing the first oxide and the second oxide in first amounts at a first ratio in a first co-adsorption film. The method 700 may further include depositing the first oxide and the second oxide in second amounts at a second ratio in a second co-adsorption film overlaying the first co-adsorption film. The molar ratio of the first oxide to the second oxide can be controlled by changing the ratio of the first precursor to the second precursor with each ALD deposition cycle. The method 700 additionally may include depositing the first oxide and the second oxide in third amounts at a third ratio in a third co-adsorption film overlaying the second co-adsorption film and so on. As described with respect to FIG. 1, the resulting amorphous oxide film deposited by method 700 may have different compositions at different thicknesses of the film.

Optionally, at block 725, the method 700 includes annealing the amorphous oxide film or article or subjecting the film or article to a heat treatment to evaporate any residual gases and/or components from the surface and to purify the amorphous oxide film. The annealing or heat treatment may be at a temperature of about 200° C. to about 1,000° C., about 300° C. to about 800° C., about 420° C. to about 600° C., or any individual temperature or sub-range within the foregoing ranges.

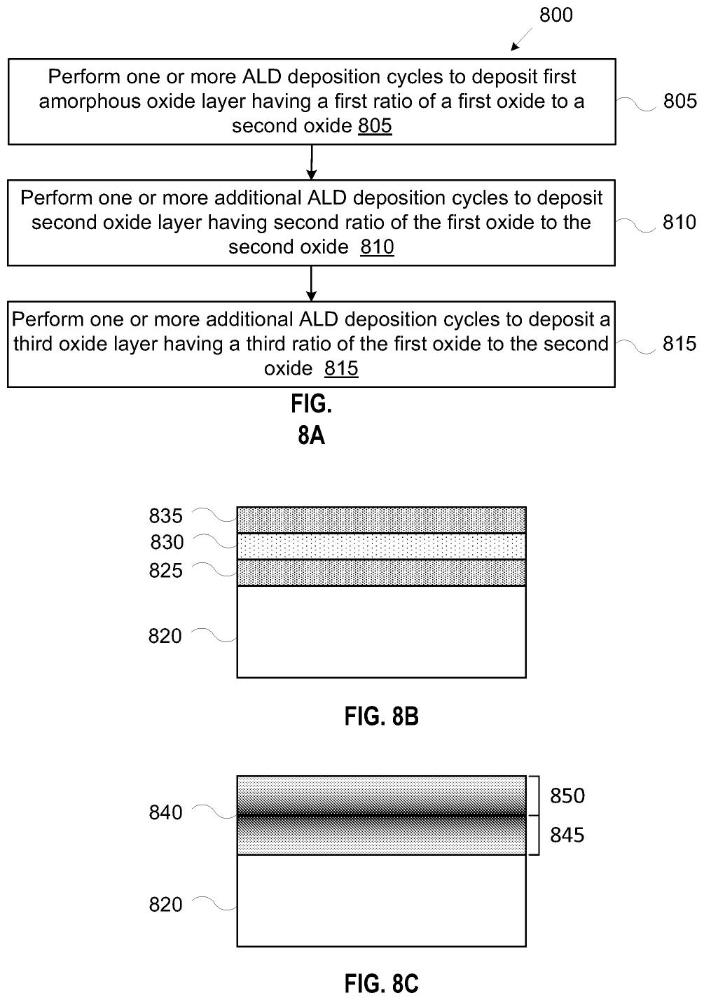

FIGS. 8A-8C illustrate an amorphous oxide film 840 deposited on a substrate 820 and a method 800 of forming the amorphous oxide film 840. The amorphous oxide film 840 may be a gradient oxide film having two or more (e.g., three) different layers, each having a different molar ratio of at least two oxides.

Method 800 includes, at block 805, performing one or more ALD deposition cycles to deposit a first amorphous oxide layer 825 on a substrate 820. The first amorphous oxide layer 825 may have a first ratio of a first oxide (e.g., ZrO₂, HfO₂) to a second oxide (e.g., SiO₂, Al₂O₃, NO). The first ratio may be about 80:1 to about 1:80, about 70:1 to about 1:70, about 50:1 to about 1:50, about 1:25 to about 25:1, or any individual ratio or sub-range within these ranges. In embodiments, the first oxide may be present in first amorphous oxide layer 825 in an amount of about 20 mol % to about 80 mol %, or any individual mol % or sub-range therein. The second oxide may be present in the first amorphous oxide layer 825 in an amount of about 20 mol % to about 80 mol %, or any individual mol % or sub-range therein.

At block 810, method 800 can include performing one or more ALD deposition cycles to deposit a second oxide layer 830 over at least a portion of the first oxide layer 825. The second oxide layer 830 can have a second ratio of the first oxide to the second oxide. The second ratio may be about 90:1 to about 1:90, about 80:1 to about 1:80, about 50:1 to about 1:50, or any individual ratio or sub-range within these ranges. In embodiments, the first oxide may be present in second amorphous oxide layer 830 in an amount of about 50 mol % to about 90 mol %, or any individual mol % or sub-range therein. The second oxide may be present in the second amorphous oxide layer 830 in an amount of about 9 mol % to about 50 mol %, or any individual mol % or sub-range therein.

At block 815, method 800 can include performing one or more ALD deposition cycles to deposit a third oxide layer 835 over at least a portion of the second oxide layer 830. The third oxide layer 835 can have a third ratio of the first oxide to the second oxide. The third ratio may be about 80:1 to about 1:80, about 70:1 to about 1:70, about 50:1 to about 1:50, about 1:25 to about 25:1, or any individual ratio or sub-range within these ranges. In embodiments, the first oxide may be present in third amorphous oxide layer 835 in an amount of about 20 mol % to about 80 mol %, or any individual mol % or sub-range therein. The second oxide may be present in the third amorphous oxide layer 835 in an amount of about 20 mol % to about 80 mol %, or any individual mol % or sub-range therein.

FIG. 8B is a representation of the amorphous oxide coating formed by the sequential deposition of the first, second and third oxide layers 825, 830, 835. As discussed above, each metal oxide layer 825, 830, 835 independently has a ratio of the first oxide to the second oxide of about 1:90 to about 90:1, or any individual ratio or sub-range therein. In embodiments, each layer 825, 830, 835 may contain a different ratio of the first and second oxides. In some embodiments, layers 825 and 835 may contain the same ratio of the first and second oxide whereas layer 830 has a different ratio. According to one or more embodiments, the first oxide is ZrO₂ or HfO₂, the second oxide is SiO₂ and the substrate 820 is silicon. In at least one embodiment, the first oxide layer 825 deposited on the silicon substrate 820 may contain more SiO₂ than, for example, than the second oxide layer 830. Silicon dioxide provides stronger adhesion to the silicon substrate 820 than ZrO₂ or HfO₂. In embodiments, the first oxide layer 825 may contain about 9 mol % to about 90 mol % SiO₂ (or any individual value or sub-range therein) and about 10 mol % to about 91 mol % ZrO₂ or HfO₂ (or any individual value or sub-range therein). The second oxide layer 830 may contain more of the second oxide (ZrO₂ or HfO₂), which has a higher dielectric constant, than the first oxide. In embodiments, the second oxide layer 830 may contain about 9 mol % to about 50 mol % SiO₂ (or any individual value or sub-range therein) and about 50 mol % to about 91 mol % ZrO₂ (or any individual value or sub-range therein). The second oxide layer 830 may be thicker than the first and third oxide layers 825, 835 and may be the bulk of the amorphous oxide film such that the film as a whole provides a dielectric constant of about 10 to about 30. Because the second oxide, ZrO₂, HfO₂, may be prone to moisture absorption, the third oxide layer 835 may be a capping or protecting layer rich in a metal oxide that is less prone to moisture absorption. For example, the third oxide layer 835 may contain about 50 mol % to about 90 mol % SiO₂ (or any individual value or sub-range therein) and about 10 mol % to about 50 mol % ZrO₂ or HfO₂ (or any individual value or sub-range therein).

FIG. 8C shows the film 840 having two gradients 845, 850 between the first and second oxides. As discussed above, each metal oxide layer 825, 830, 835 as deposited may have a thickness of about 1 Å to about 1000 Å, about 1 Å to about 600 Å, about 1 Å to about 50 Å, about 1 Å to about 25 Å, about 1 Å to about 10 Å, or any individual thickness or sub-range within these ranges. At these thicknesses, each deposited layer combines or mixes with the underlying layer, such that the resulting film 840 as a whole includes a gradient (shown in FIG. 8C) in concentration of the first oxide and the second oxide. For example, the amorphous oxide film 840 may contain a first concentration gradient 845 between the substrate 820 and a center of the film, that is, in the region where the second oxide layer was deposited. Film 840 also may contain a second concentration gradient 850 between the center of the film and a top surface of the film.

### ILLUSTRATIVE EXAMPLES

The following examples are set forth to assist in understanding the disclosure and should not be construed as specifically limiting the disclosure described and claimed herein. Such variations of the disclosure, including the substitution of all equivalents now known or later developed, which would be within the purview of those skilled in the art, and changes in formulation or minor changes in experimental design, are to be considered to fall within the scope of the disclosure incorporated herein.

### Example 1—Evaluation of Hysteresis as a Function of Amorphous Oxide Film Composition

Samples were prepared by depositing ZrO₂ films doped with SiO₂ on silicon substrates using a PEALD method in accordance with method 500. The composition of each sample was as set forth in Table 1.

TABLE 1
ZrO₂ films doped with SiO₂ on Si substrates

| | | | DIPAS | |
|---|---|---|---|---|
| Molar Ratio | Crystallinity | TEMAZ | per super- | Hysteresis |
| ZrO₂:SiO₂ | (XRD) | per super-cycle | cycle | (V) |
| 20:2 | Tetragonal/Cubic | 20 | 2 | 21.5 |
| 20:3 | Amorphous | 20 | 3 | 21.3 |
| 20:3 | Amorphous | 40 | 6 | 0.556 |
| 5:1 | Amorphous | 40 | 8 | 0.049 |

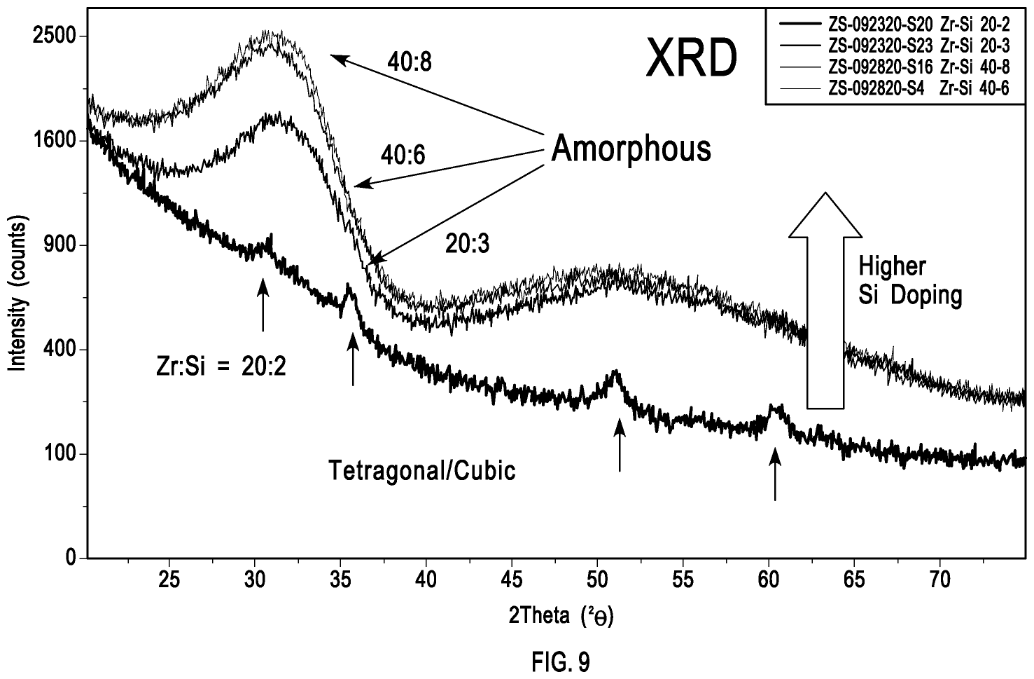

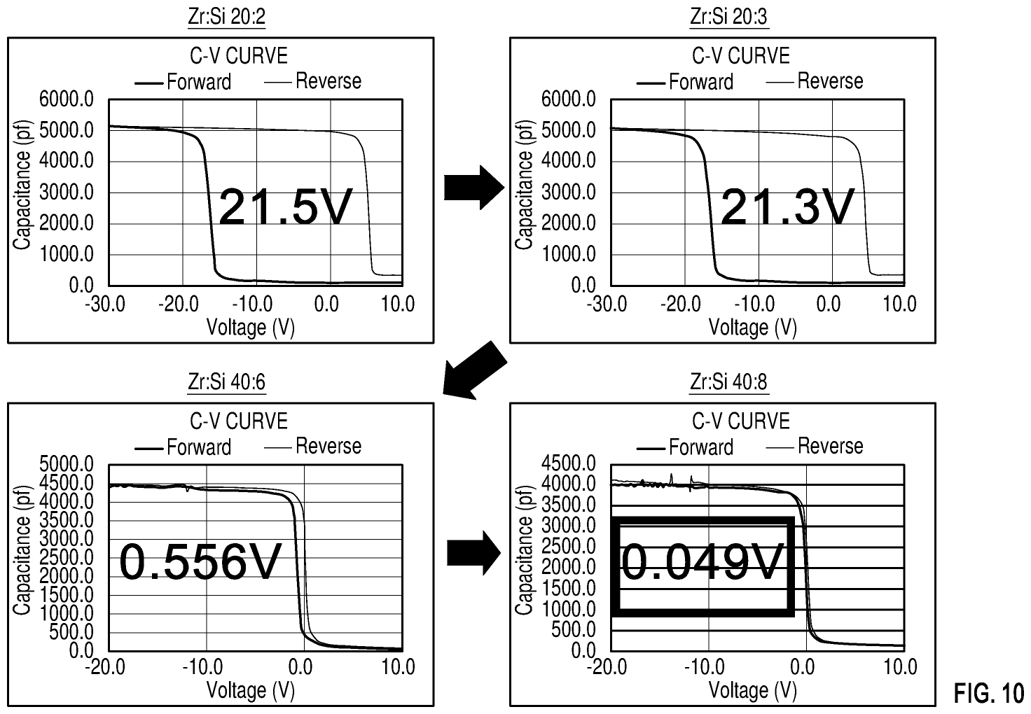

An X-ray Diffraction (XRD) spectrum was obtained for each sample and the results are shown in FIG. 9. As shown in Table 1 and FIG. 9, the crystallinity of the film was tetragonal or cubic when the ZrO₂ and the SiO₂ were present at a ratio of 20:2. At the other three ratios, the ZrO₂ doped with SiO₂ film was amorphous. It was determined that the ZrO₂:SiO₂ film becomes amorphous as the Si₂ doping increases to about 9.7 mol %. The hysteresis of each sample also was measured and the results are presented in FIG. 10. As shown in FIG. 10 and Table 1, the hysteresis voltage decreased as the amount of SiO₂ doping in the film increased.

### Example 2—Comparison of High Dielectric Constant Gate Insulator Film Compositions

Samples of different material compositions were prepared using PEALD. The samples included a silicon substrate coated with a metal oxide film and having the compositions as shown in Table 2.

TABLE 2
High-K Gate Insulator Films Deposited by PEALD

| | ALD | ALD | SiO₂ + ZrO₂ + SiO₂ | SiO₂:a-ZrO₂ | SiO₂:a:ZrO₂ |
|---|---|---|---|---|---|
| Film | ZrO₂ | SiO₂ | Stack | (ZrO₂-rich) | (SiO₂-rich) |
| TEMAZ | 10 | N/A | 10 | 10 | 10 |
| Power (kW) | | | | | |
| DIPAS Power | N/A | 4 | 4 | 4 | 4 |
| (kW) | | | | | |
| ZrO₂ Content | 100 | 0 | 75 | 88.5 | 25.9 |
| (At. %) | | | | | |
| SiO₂ Content | 0 | 100 | 25 | 12.5 | 74.1 |
| (At. %) | | | | | |
| Leakage | 1.0E⁻⁸ | 2.8E⁻¹⁰ | 1.2E⁻⁹ | 4.7E⁻⁸ | 2.2E⁻¹⁰ |
| Current | | | | | |
| (A/cm²) | | | | | |
| Breakdown | 3.5 | 12.9 | 8.3 | 4.4 | 12.9 |
| Voltage (Vbd) | | | | | |
| (MV/cm) | | | | | |
| Dielectric | 31.6 | 4.14 | 10.62 | 12.3 | 4.34 |
| Constant (k) | | | | | |
| Flat-band | −15.2 | −2.065 | −0.287 | 0.590 | 0.533 |
| Voltage (Vfb) | | | | | |
| (V) | | | | | |
| Δ Vfb | 20.5 | 0.186 | −0.073 | 0.049 | 0.059 |
| (V) | | | | | |

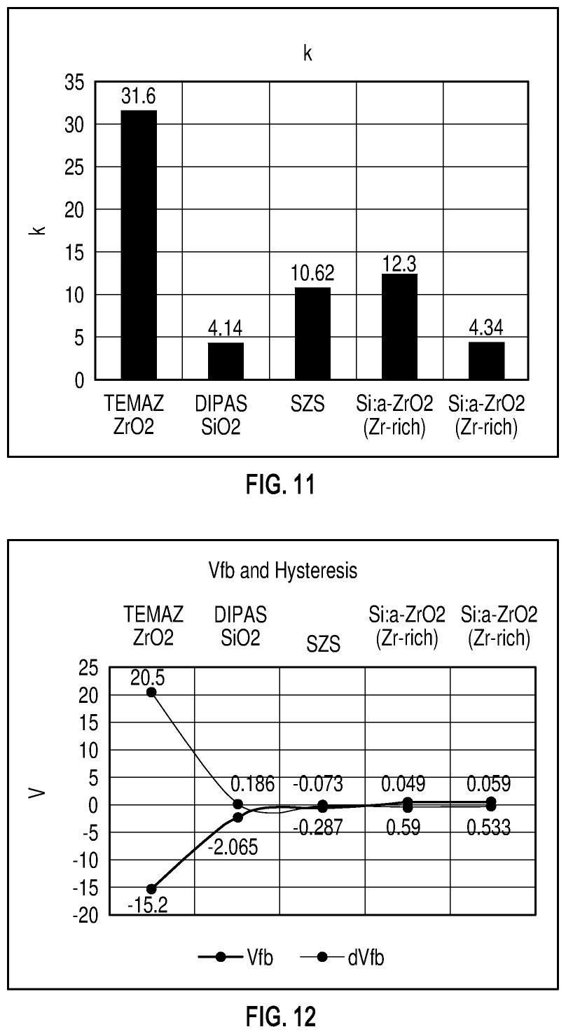

As shown in FIG. 11 and Table 2, the dielectric constant (k) of the samples ranged from 4.14 for a pure SiO₂ gate insulator film to 31.6 for a pure ZrO₂ gate insulator film. As shown, the samples having both ZrO₂ and SiO₂ had a k value between 4.14 and 31.6. The Zr-rich sample was an amorphous gate insulator material that demonstrated the highest k value of the samples that contained both the ZrO₂ and the SiO₂. As shown in FIG. 12 and Table 2, the Zr-rich sample had a low flat band voltage shift as well as low hysteresis. Doping ZrO₂ with SiO₂ provides an amorphous crystallinity and results in film properties suitable for a gate insulator. Notably, the Si-rich gate insulator film had a higher dielectric constant than the pure DIPAS SiO₂ gate insulator film.

The preceding description sets forth numerous specific details such as examples of specific systems, components, methods, and so forth, in order to provide a good understanding of several embodiments of the present disclosure. It will be apparent to one skilled in the art, however, that at least some embodiments of the present disclosure may be practiced without these specific details. In other instances, well-known components or methods are not described in detail or are presented in simple block diagram format in order to avoid unnecessarily obscuring the present disclosure. Thus, the specific details set forth are merely exemplary. Particular implementations may vary from these exemplary details and still be contemplated to be within the scope of the present disclosure.

As used herein, the singular forms “a,” “an,” and “the” include plural references unless the context clearly indicates otherwise. Thus, for example, reference to “a precursor” includes a single precursor as well as a mixture of two or more precursors; and reference to a “reactant” includes a single reactant as well as a mixture of two or more reactants, and the like.

Reference throughout this specification to “one embodiment” or “an embodiment” means that a particular feature, structure, or characteristic described in connection with the embodiment is included in at least one embodiment. Thus, the appearances of the phrase “in one embodiment” or “in an embodiment” in various places throughout this specification are not necessarily all referring to the same embodiment. In addition, the term “or” is intended to mean an inclusive “or” rather than an exclusive “or.” When the term “about” or “approximately” is used herein, this is intended to mean that the nominal value presented is precise within ±10%, such that “about 10” would include from 9 to 11.

The term “at least about” in connection with a measured quantity refers to the normal variations in the measured quantity, as expected by one of ordinary skill in the art in making the measurement and exercising a level of care commensurate with the objective of measurement and precisions of the measuring equipment and any quantities higher than that. In certain embodiments, the term “at least about” includes the recited number minus 10% and any quantity that is higher such that “at least about 10” would include 9 and anything greater than 9. This term can also be expressed as “about 10 or more.” Similarly, the term “less than about” typically includes the recited number plus 10% and any quantity that is lower such that “less than about 10” would include 11 and anything less than 11. This term can also be expressed as “about 10 or less.”

Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to illuminate certain materials and methods and does not pose a limitation on scope. No language in the specification should be construed as indicating any non-claimed element as essential to the practice of the disclosed materials and methods.

Although the operations of the methods herein are shown and described in a particular order, the order of the operations of each method may be altered so that certain operations may be performed in an inverse order or so that certain operation may be performed, at least in part, concurrently with other operations. In another embodiment, instructions or sub-operations of distinct operations may be in an intermittent and/or alternating manner.

It is to be understood that the above description is intended to be illustrative, and not restrictive. Many other embodiments will be apparent to those of skill in the art upon reading and understanding the above description. The scope of the disclosure should, therefore, be determined with reference to the appended claims, along with the full scope of equivalents to which such claims are entitled.

What is claimed is:

1. An article, comprising:
a substrate; and
an amorphous oxide film overlaying at least a portion of the substrate, wherein the amorphous oxide film comprises a first oxide and a second oxide,
wherein the first oxide comprises zirconium oxide (ZrO₂), hafnium oxide (HfO₂) or a combination thereof,
wherein the second oxide comprises silicon dioxide (SiO₂), aluminum oxide (Al₂O₃), nitric oxide (NO) or combinations thereof,
wherein the amorphous oxide film is conformal and comprises a porosity of less than about 1%, and
wherein the amorphous oxide film comprises a dielectric constant (k) of about 8 to about 28.

2. The article of claim 1, wherein the substrate comprises silicon (Si), germanium (Ge), one or more group III-V semiconductor, InP, InAs, bare glass (SiO₂) or combinations thereof.

3. The article of claim 1, wherein a molar ratio of the first oxide to the second oxide is about 1:1 to about 100:1.

4. The article of claim 1, wherein the first oxide comprises ZrO₂ and the second oxide comprises SiO₂.

5. The article of claim 1, wherein the second oxide is a doping metal oxide, and wherein the amorphous oxide film comprises the second metal in an amount of about 1 mol % to about 50 mol %.

6. The article of claim 1, wherein the first oxide comprises ZrO₂, wherein the second oxide comprises SiO₂, and wherein the SiO₂ is present in an amount of at least about 9 mol % to about 50 mol %.

7. The article of claim 1, wherein the amorphous oxide film comprises a thickness of at least about 200 Å to about 2,000 Å.

8. The article of claim 1, wherein the amorphous oxide film comprises a first ratio of the first metal to the second metal within a first thickness of the amorphous oxide film, a second ratio of the first metal to the second metal within a second thickness of the amorphous oxide film, and a third ratio of the first metal to the second metal within a third thickness of the amorphous oxide film.

9. A transistor structure, comprising:
a gate;
a source;
a drain; and
an amorphous oxide film separating the gate from at least one of the source or the drain,
wherein the amorphous oxide film comprises a first oxide and a second oxide,
wherein the first oxide comprises zirconium oxide (ZrO₂), hafnium oxide (HfO₂) or a combination thereof,
wherein the second oxide comprises silicon dioxide (SiO₂), aluminum oxide (Al₂O₃), nitric oxide (NO) or combinations thereof,
wherein the amorphous oxide film comprises a porosity of less than about 1%, and
wherein the amorphous oxide film comprises a dielectric constant (k) of about 8 to about 28.

10. The transistor structure of claim 9, wherein the substrate comprises silicon (Si), germanium (Ge), one or more group III-V semiconductor, InP, InAs, bare glass (SiO₂) or combinations thereof.

11. The transistor structure of claim 9, wherein a molar ratio of the first oxide to the second oxide is about 1:1 to about 100:1.

12. The transistor structure of claim 9, wherein the first oxide comprises ZrO₂ and the second oxide comprises SiO₂.

13. The transistor structure of claim 9, wherein the second oxide is a doping metal oxide, and wherein the amorphous oxide film comprises the second metal in an amount of about 1 mol % to about 50 mol %.

14. The transistor structure of claim 9, wherein the first oxide comprises ZrO₂, wherein the second oxide comprises SiO₂, and wherein the SiO₂ is present in an amount of at least about 9 mol % to about 50 mol %.

15. The transistor structure of claim 9, wherein the amorphous oxide film comprises a thickness of at least about 200 Å to about 2,000 Å.

16. The transistor structure of claim 9, wherein the amorphous oxide film comprises a first ratio of the first oxide to the second oxide within a first thickness of the amorphous oxide film, a second ratio of the first oxide to the second oxide within a second thickness of the amorphous oxide film, and a third ratio of the first oxide to the second oxide within a third thickness of the amorphous oxide film.

17. A method of forming an amorphous oxide film, comprising:
performing a plasma-enhanced atomic layer deposition (ALD) process to form an amorphous oxide film comprising a first oxide and a second oxide, wherein the first oxide comprises ZrO₂, HfO₂ or a combination thereof, wherein the second oxide comprises SiO₂, Al₂O₃, NO, or combinations thereof, wherein the amorphous oxide film comprises a dielectric constant (k) of about 8 to about 28, and wherein performing the plasma-enhanced ALD process comprises:
performing one or more ALD deposition super-cycles, each ALD deposition super-cycle comprising:
performing one or more first ALD deposition cycles to deposit a first oxide layer of the first oxide; and
performing one or more second ALD deposition cycles to deposit a second oxide layer to form the amorphous oxide layer of the second oxide.

18. The method of claim 17, wherein:
each of the one or more first ALD deposition cycles comprises:
contacting a surface with at least one of a Zr precursor or an Hf precursor in a first half reaction; and
contacting the surface with a first oxygen reactant in a second half reaction to form the first oxide layer; and
each of the one or more second ALD deposition cycles comprises:
contacting the surface with at least one of a Si precursor, an Al precursor or an N precursor in a third half reaction; and
contacting the surface with the first oxygen reactant or a second oxygen reactant in a fourth half reaction to form the second oxide layer.

19. The method of claim 17, wherein the Zr precursor is used for the first half reaction, wherein the Si precursor is used for the second half reaction, and wherein the first oxygen reactant and the second oxygen reactant is independently selected from a group consisting of water (H₂O), ozone (O₃), oxygen (O₂), hydrogen peroxide (H₂O₂) and oxygen radical (O⁻).

20. The method of claim 17, wherein the plasma-enhanced atomic layer deposition process further comprises:
performing one or more third deposition cycles to deposit an adhesion metal oxide layer on the surface before performing the one or more ALD deposition super-cycles, wherein the adhesion metal oxide layer comprises one or more of SiO₂, Al₂O₃, HfO₂, SiCON, SiC or combinations thereof.
